(19) United States
(12) Patent Application Publication
(10) Pub. No.: US 2026/0237450 A1
(43) Pub. Date: Aug. 13, 2026

(54) HANDLING SYSTEM MEMORY MANAGEMENT UNIT (SMMU) FAULTS IN HYPERVISOR

(71) Applicant: QUALCOMM INCORPORATED, San Diego, CA (US)

(72) Inventors: Kartikey SINGH, New Delhi (IN); Swapnil Kailas KAUTHALE, Hyderabad (IN); Debankan ROY, Kolkata (IN)

(21) Appl. No.: 19/052,043

(22) Filed: Feb. 12, 2025

(51) Int. Cl. G11C 29/18; G06F 9/455

(52) U.S. Cl. CPC G11C 29/18; G06F 9/45558; G06F 2009/45583; G06F 2009/45591; G11C 2029/1806

(57) ABSTRACT

A hypervisor may re-map a data stream from an address translation context bank to a termination context bank in response to detecting an address translation fault by a system memory management unit (SMMU). The termination context bank may be configured to terminate address translations, so that potential disruptions from further attempted address translations in the data stream may be avoided.

### DESCRIPTION OF THE RELATED ART

A computing device may include multiple subsystems, cores, or other components. Such a computing device may be, for example, a portable computing device, such as a cellular telephone or smartphone, a desktop, laptop, palmtop or tablet computer, a so-called Internet-of-Things device, a wearable device, an automotive computing device, etc. The multiple subsystems, cores, or other components of a computing device may be included within different chips or in the same integrated circuit chip. A “system-on-chip” or “SoC” is an example of a chip that integrates numerous components to provide system-level functionality.

For example, a SoC may include one or more types of processors, such as central processing units (CPUs), graphics processing units (GPUs), digital signal processors (DSPs), neural processing units (NPUs), etc. A SoC may include other processing subsystems, such as a transceiver or “modem” subsystem that provides wireless connectivity, etc. A SoC may also include peripheral device subsystems, such as cameras, displays, sensors, etc. Various subsystems may operate in a virtual machine (VM) context, where a hypervisor controls aspects of multiple VMs.

In a traditional system having a single high-level operating system (HLOS), a memory management unit (MMU) may translate virtual addresses referenced by processors in the context of memory transaction requests into physical addresses in a system memory. An MMU may perform additional functions, such as handling error conditions (e.g., translation faults). In a system having VMs and a hypervisor, system memory management units (SMMUs), which are analogous to MMUs in a non-VM context, may translate virtual addresses referenced by VM memory transaction requests into physical addresses before passing the memory transaction requests into a system interconnect.

Generally, an SMMU first translates a virtual address into an intermediate physical address (IPA) under control of a VM, an operation referred to as “stage-1” translation. Then, the SMMU translates the IPA into a physical address under control of the hypervisor, an operation referred to as “stage-2” translation. The VM may control stage-1 translation, including handling any stage-1 translation faults, while the hypervisor may control stage-2 translation, including handling any stage-2 translation faults. The manner in which the hypervisor handles such stage-2 translation faults may affect system operation. For example, a hypervisor may reset or restart one or more VMs or even the entire SoC in response to a stage-2 translation fault. It would be desirable to handle translation faults in a manner that is not disruptive to system operation.

### SUMMARY OF THE DISCLOSURE

Systems, methods, computer-readable media, and other examples of handling system memory management unit (SMMU) translation faults in a computing device are disclosed.

An exemplary method may include translating, by an SMMU, an address associated with a data stream. The method may further include detecting, by a hypervisor, a translation fault associated with translating the address. The method may still further include re-mapping, by the hypervisor, the data stream from an address translation context bank to a termination context bank in response to detecting the translation fault. In contrast with an address translation context bank that is configured to enable address translations, the termination context bank may be configured to terminate address translations.

An exemplary system for handling address translation faults in a computing device may include an SMMU and a hypervisor. The SMMU may be configured to translate addresses associated with a data stream. The hypervisor may be configured to detect a translation fault associated with the SMMU translating an address. The hypervisor may further be configured to re-map the data stream from an address translation context bank to a termination context bank in response to detecting the translation fault.

An exemplary computer-readable medium may comprise a non-transitory medium on which computer-executable code is stored. The computer-executable code may include instructions for configuring a plurality of address translation context banks and a termination context bank. The computer-executable code may further include instructions for detecting an address translation fault associated with a data stream. The computer-executable code may still further include instructions for re-mapping the data stream from one of the address translation context banks to the termination context bank in response to detecting an address translation fault associated with the data stream.

### BRIEF DESCRIPTION OF THE DRAWINGS

In the Figures, like reference numerals refer to like parts throughout the various views unless otherwise indicated. For reference numerals with letter character designations such as “101A” or “101B”, the letter character designations may differentiate two like parts or elements present in the same Figure. Letter character designations for reference numerals may be omitted when it is intended that a reference numeral encompass all parts having the same reference numeral in all Figures.

FIG. 1 is a block diagram of a system for handling system memory management unit (SMMU) translation faults, in accordance with exemplary embodiments.

FIG. 2 is a functional block diagram showing virtual machines and a hypervisor configured to handle SMMU translation faults, in accordance with exemplary embodiments.

FIG. 3 is a sequence diagram illustrating handling SMMU translation faults, in accordance with exemplary embodiments.

FIG. 4 is a flow diagram illustrating a method for handling SMMU translation faults, in accordance with exemplary embodiments.

FIG. 5 is a software diagram of a hypervisor, in accordance with exemplary embodiments.

FIG. 6 is a block diagram of an automotive computing system having an SMMU translation fault handling feature, in accordance with exemplary embodiments.

### DETAILED DESCRIPTION

The word “exemplary” is used herein to mean “serving as an example, instance, or illustration.” The word “illustrative” may be used herein synonymously with “exemplary.” Any aspect described herein as “exemplary” is not necessarily to be construed as preferred or advantageous over other aspects.

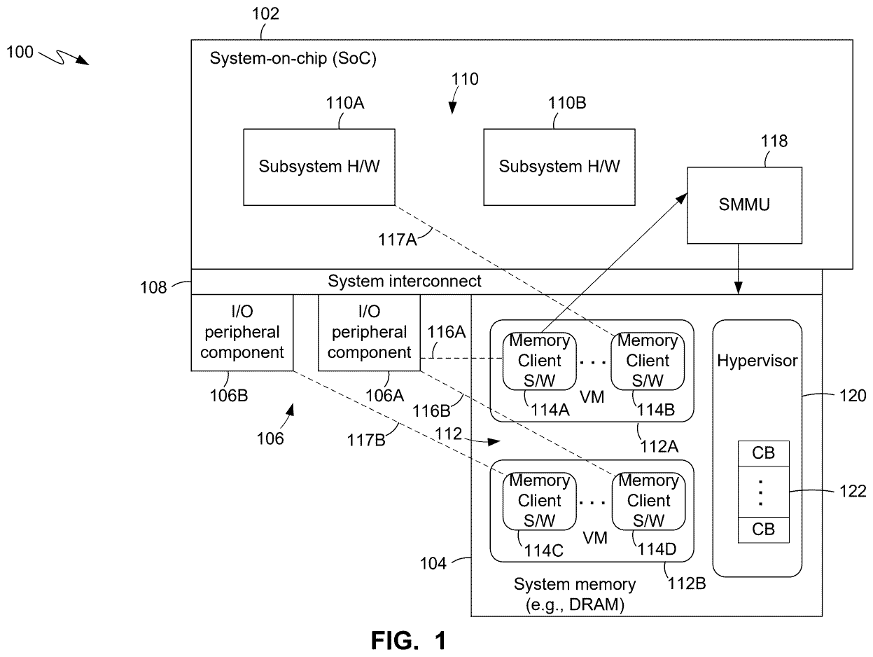

As shown in FIG. 1, in an illustrative or exemplary embodiment a system 100 may include a system-on-chip (SoC) 102, a system memory 104, any number of input/output (I/O) components 106, and a system interconnect 108. Although not explicitly shown in FIG. 1 for purposes of clarity, the system 100 may be included in a computing device, such as, for example, an automotive computing device, Internet-of-Things device, or other device in which operation of the system 100 could affect safety. Nevertheless, in other examples such a system could be included in a cellular telephone or smartphone, a desktop, laptop, palmtop or tablet computer, a wearable device, etc. The I/O components 106, such as a first I/O peripheral component 106A and a second I/O peripheral component 106B, may comprise data sources, such as cameras, sensors, etc., and data destinations, such as displays, etc. In an automotive computing device example, a sensor may be an example of an I/O component 106 that is a data source, while a dashboard display may be an example of an I/O component 106 that is a data destination.

The SoC 102 may include any number of subsystems 110, such as a first subsystem 110A and a second subsystem 110B. Examples of subsystems 110 may include a central processing unit (CPU), a graphics processing unit (GPU), an audio processor, etc. The subsystems 110 as shown in FIG. 1 are intended to primarily represent hardware (H/W) or circuitry. Software aspects relating to the subsystems 110 that are relevant to the solutions described herein are described below.

The subsystems 110 and I/O components 106 may be associated with client software (e.g., drivers, etc.), conceptually shown in FIG. 1 as residing in one of a number of virtual machines (VMs) 112, such as a first VM 112A and a second VM 112B. For example, the first I/O component 106A may be associated (as indicated by the line 116A) with client software 114A in the first VM 112A as well as associated (as indicated by the line 116B) with client software 114D in the second VM 112B. Similarly, the first subsystem 110A may be associated (as indicated by the line 117A) with client software 114B in the first VM 112A, and the second I/O component 106B may be associated (as indicated by the line 117B) with client software 114C in the second VM 112B. The foregoing associations are intended only as examples of associations between client software and various subsystem or I/O device hardware, and many other associations are possible. Nevertheless, note in this example that any subsystem 110 or I/O component 106 (e.g., the first I/O component 106A) may be associated with client software in more than one of the VMs 112. Stated another way, more than one VM 112 may have access to the same subsystem or I/O device hardware. A data path that may be established between that subsystem or I/O device hardware and one of the VMs 112 may be referred to as a “stream.” The same subsystem or I/O device hardware may provide streams to multiple VMs 112.

The subsystems 110 and I/O components 106 (including associated client software) may function as memory clients with respect to the system memory 104. That is, any of the subsystems 110 and I/O components 106 may initiate memory transactions (i.e., read or write operations) with the system memory 104. For example, an application (not shown) executing on a processor such as a CPU may invoke any of the client software 114A-114C (e.g., driver software) to request a memory transaction. The application may reference virtual addresses in such memory transactions.

The SoC 102 may include a system memory management unit (SMMU) 118 configured to translate between the virtual address space used by, for example, application programs, and the physical address space of the system memory 104. This address translation may be performed in two stages. The first stage or “stage-1” translation may be managed or controlled by the one of the VMs 112 having the client software 114A-114D being invoked by the application. The second stage or “stage-2” translation may be managed or controlled by a hypervisor 120. The hypervisor 120 may maintain multiple context banks 122 that may be used in the address translation. Context banks 122 that are used in address translation may include information such as, for example, the base address of a page table (not shown) as well as attributes (not shown) that may be used by the SMMU 118. A context bank 122 may be analogous to a memory management unit (MMU) used in a non-VM/hypervisor-based system (not shown).

When the SMMU 118 has successfully completed an address translation, the output of the SMMU 118 may include the resulting physical address. The SMMU 118 may place that physical address on the system interconnect 108 to be used by the system memory 104. Note that the system interconnect 108 operates analogously to a bus, providing data communication among the SoC 102, system memory 104, I/O components 106, etc. The system interconnect 108 may be referred to as a bus, a system interconnect bus, a system interconnect fabric, etc. The system interconnect 108 may include features such as address decoding, multiplexing, error indication, etc.

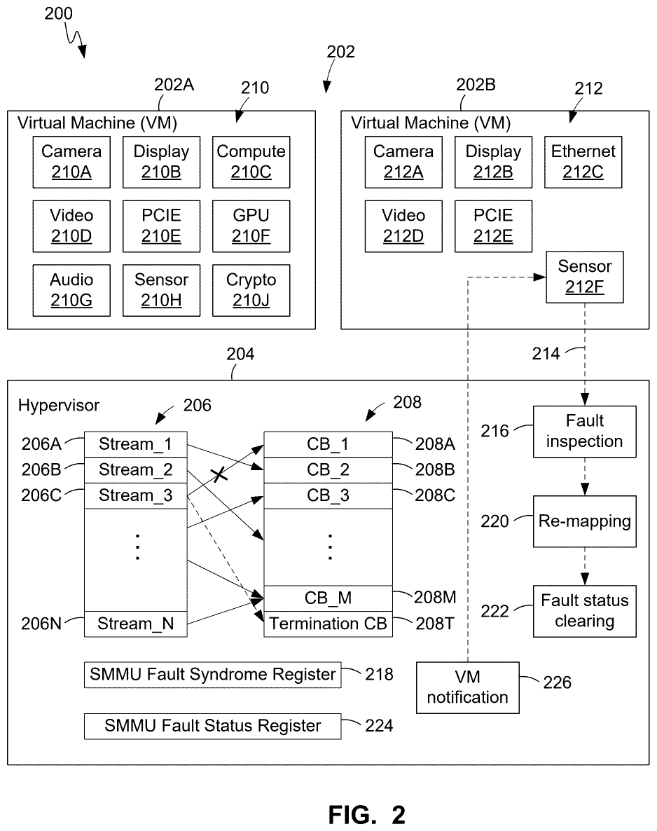

As shown in FIG. 2, in a system 200 having multiple VMs 202 and a hypervisor 204, multiple streams 206, such as a first stream 206A through an Nth stream 206N, may be mapped to multiple context banks (CBs) 208, such as first context bank 208A through an Mth context bank 208M (where the mappings are indicated by arrows, and N and M may represent any number of streams 206 and context banks 208, respectively). Any stream 206 may be mapped to any context bank 208, and more than one stream 206 may be mapped to the same context bank 208. In the illustrated example: the first stream 206A (Stream_1) may be mapped to a second context bank 208B (CB_2); a second stream 206B (Stream_2) may be mapped to some other context bank 208 (not separately shown); a third stream 206C (Stream_3) may be mapped to the first context bank 208A (CB_1); some other stream (not separately shown) may be mapped to the third context bank 208C (CB_3); the Nth stream 206N (Stream_N) may be mapped to the Mth context bank 208M (CB_M); and still some other stream 206 (not separately shown) may also be mapped to the Mth context bank 208M.

In addition to the (address translation) context banks 208A-208M, the context banks 208 may include a termination context bank 208T. The function of the termination context bank 208T is described below. Nevertheless, it may be noted here that while the context banks 208A-208M may be configured to enable the SMMU (not shown in FIG. 2) to perform stage-2 address translations under control of the hypervisor 204, the termination context bank 208T may be configured to terminate address translation. That is, address translation is not performed when a stream 206 is mapped to the termination context bank 208T as described below. As a result of the termination of address translation, the memory transaction will be terminated and reported back to the client, as described below.

In the example illustrated in FIG. 2, the VMs 202 may include a first VM 202A and a second VM 202B. The first VM 202A may include any number of memory clients 210, such as, for example: a camera client 210A, a display client 210B, a compute (e.g., CPU) client 210C, a video client 210D, a Peripheral Component Interconnect Express (PCIe) client 210E, a GPU client 210F, an audio client 210G, a sensor client 210H, a cryptographic processing client 210J, etc. The second VM 202B may similarly include any number of memory clients 212, such as, for example: a camera client 212A, a display client 212B, an Ethernet client 212C, a video client 212D, a PCIe client 212E, a sensor client 212F, etc. Note in this example that the camera clients 210A and 212A may share the same camera components (e.g., hardware), the display clients 210B and 212B may share the same display components (e.g., hardware), the video clients 210D and 212D may share the same video processors, the PCIe clients 210E and 212C may share the same PCIe components, and the sensor clients 210H and 212F may share the same sensor components, etc. Processors may be examples of hardware components that may be included in the SoC 102, as described above with regard to FIG. 1. Sensors, cameras, displays, etc., may be examples of I/O peripheral components, as described above with regard to FIG. 1.

In the illustrated example, the first VM 202A and second VM 202B may differ in one or more respects. For example, the first VM 202A may be oriented toward general-purpose use cases (i.e., tasks or processes), while the second VM 202B may be oriented toward use cases that could impact safety or “safety-related” use cases. For example, in an automotive computing system the second VM 202B may support Adaptive Driver Assistance Systems (ADAS), while the first VM 202A may support in-vehicle infotainment or other more general or less safety-related use cases. It may be advantageous to handle address translation faults associated with a safety-related VM in a manner that is least disruptive to vehicle operation, thereby promoting safety. The solutions for handling address translation faults described herein may provide such advantages. Nevertheless, handling address translation faults associated with a safety-related VM is intended only an example, and the solutions described herein are not limited to safety-related systems.

In an example of operation of the system 200, one of the memory clients 210 or 212, such as, for example, the sensor client 212F of the second VM 202B, may be processing a memory transaction. For example, the sensor client 212F may be sensing data relating to the vehicle's environment or operation and providing the sensed data to the system memory 104 (FIG. 1) using a direct memory access (DMA) operation. There may be, for example, one or more executing application programs (not shown) that are using the sensor client 212F (in the manner of a driver for the sensor hardware). As the data is being passed through to the system memory 104, the associated virtual addresses (VAs) provided by the sensor client 212F are translated into physical addresses (PAs) by the SMMU 118 (FIG. 1). As noted above, the address translation may occur in two stages, where the stage-1 translation from VA to intermediate physical address (IPA) may be managed by the second VM 202B (where the sensor client 212F is executing) using a stage-1 page table (not shown), and the stage-2 translation from IPA to PA may be managed by the hypervisor 204. In performing a stage-2 translation, a translation fault may occur. In FIG. 2, the occurrence of a stage-2 translation fault involving a data stream from the sensor client 212F is conceptually indicated by an arrow 214.

A stage-2 translation fault could occur if, for example, the SMMU 118 attempts to translate a faulty IPA. A faulty IPA could exist because, for example, the second VM 202B may earlier have set up a stage-1 page table (not shown) incorrectly. When the SMMU 118 determines there is a stage-2 translation fault, the SMMU 118 may issue an interrupt request (not shown). The hypervisor 204 may include fault inspection logic 216. The fault inspection logic 216 may configure the hypervisor 204 to read a fault syndrome register 218 in response to the interrupt request. The hypervisor 204 may determine from the contents of the fault syndrome register 218 that, in this example, the reason for the interrupt request is a stage-2 translation fault.

Alternatively to the solutions described herein, in response to detecting a stage-2 translation fault, a hypervisor could, for example, shut down or disable the entire VM having the client experiencing the faulty translation, or shut down or disable the SMMU. However, shutting down or disabling the VM or SMMU may be disruptive and, for a safety-related VM, may impact safe operation. For example, if the second VM 202B were shut down or restarted, there may be a period of time during which a sensed data stream associated with the sensor client 212F may be interrupted. Another alternative response could be to ignore the translation fault, but that would not prevent the client from repeating the same transaction, leading to the same translation fault. Yet another alternative could be to disable the stage-2 context bank involved in the translation (i.e., the address translation context bank to which the stream having the faulty address is mapped). However, disabling the address translation context bank could adversely impact other clients whose streams are mapped to that context bank. The following solution may provide advantages over the foregoing alternatives. Nevertheless, in some examples this solution may be included in addition to or in combination with the foregoing alternatives or others.

The hypervisor 204 may also include re-mapping logic 220. In the example illustrated in FIG. 2, the sensor client 212F may be associated with, for example, the third stream 206C (and could, in some examples, be associated with other streams as well). In response to a stage-2 translation fault, the hypervisor 204 may be configured by the re-mapping logic 220 to re-map the third stream 206C from the first address translation context bank 208A to the termination context bank 208T. That is, in accordance with this re-mapping, the third stream 206C is no longer mapped to the first address translation context bank 208A (as indicated by the “X” through the arrow from the third stream 206C to the first address translation context bank 208A) and instead becomes mapped to the termination context bank 208T (as indicated by the broken-line arrow from the third stream 206C to the termination context bank 208T. Following this re-mapping, the SMMU 118 (FIG. 1) will be directed to use the termination context bank 208T for further stage-2 translations associated with the third stream 206C and will no longer be directed to use the first context bank 208A for such further stage-2 translations associated with the third stream 206C.

The termination context bank 208T may be configured to terminate or abort address translations. That is, when the SMMU 118 (FIG. 1) attempts to perform a stage-2 translation using the termination context bank 208T, the address translation operation is terminated or aborted, i.e., no translation is completed, and the SMMU 118 does not output a translated address (i.e., a physical address) onto the system interconnect 108 (FIG. 1).

The hypervisor 204 may further include fault status clearing logic 222. The hypervisor 204 may be configured by the fault status clearing logic 222 to clear a fault status indication in a fault status register 224 following the re-mapping. Clearing the fault status indication hides or masks the occurrence of the translation fault from the VMs 202. As the VMs 202 will not be aware that a translation fault occurred, actions that a VM 202 may otherwise have initiated in response to a translation fault, which may be disruptive to ongoing system operation, may be avoided.

The hypervisor 204 may include VM notification logic 226. The hypervisor 204 may be configured by the VM notification logic 226 to provide a notification to the VM 202B associated with the address translation fault. This notification may include the hypervisor 204 outputting a null address or other unique address, such as, for example, 0x0 (the number zero in hexadecimal notation), onto the system interconnect 108 (FIG. 1) as a substitute in the absence of a translated address being output by the SMMU 118 onto the system interconnect 108. In response to the null address (e.g., 0x0), the system interconnect 108 may report a “bus error” to the sensor client 212F. When the sensor client 212F receives a bus error in response to a memory transaction it initiated, the sensor client 212F may may decode error syndrome bits (not shown) on the system interconnect 108 to determine which stream is associated with the bus error. The sensor client 212F may then take remedial action, i.e., to recover from the error. For example, the sensor client 212F or the second VM 202B may attempt to rectify any faulty set-up of the related stage-1 page table (not shown) that may have led to the stage-2 address translation fault. Although in this example the sensor client 212 experiences the address translation fault, in other examples any other memory client 210, 212, etc., experiencing such an address translation fault could similarly take remedial action.

Aspects of the remedial action may be based on use case. For example, the same sensor hardware may be in use by more than one application program (or more than one executing process, thread, etc.), each associated with a different stream. The sensor client 212F may determine, for example, which such use case the third stream 206C is associated with, and may then shut down or restart that only the affected use case, leaving any other executing use cases not affected by the translation fault to continue operating.

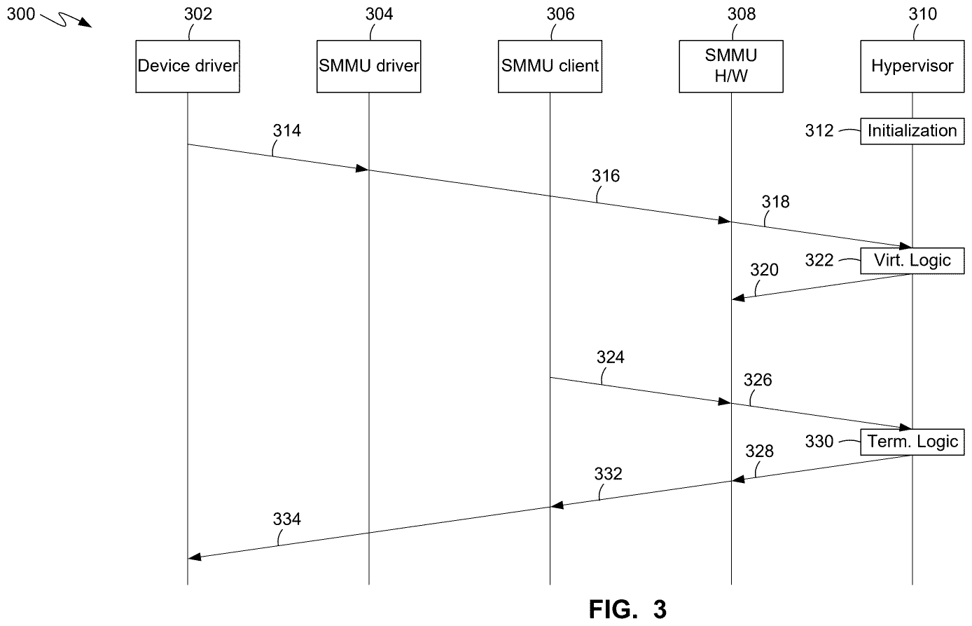

In FIG. 3, a sequence diagram 300 illustrates examples of signal communication in a system for handling SMMU translation faults. The system may include a device driver 302, an SMMU driver 304, an SMMU client 306, SMMU hardware 308, and a hypervisor 310. The device driver 302 and SMMU driver 304 may be examples of software elements included in the above-described client software 114A-114D (FIG. 1) executing on the virtual machines 112, in the clients 210 and 212 (FIG. 2), etc. The SMMU client 306 may be a software element executing on the SMMU hardware 308. The SMMU client 306 and SMMU hardware 308 may together be an example of the above-described SMMU 118 (FIG. 1).

At, for example, SoC boot time, the hypervisor 310 may perform an initialization 312 or configuration of the termination context bank. The hypervisor may configure the termination context bank as a stage-2 context bank, set the mode of this context bank to terminate (i.e., abort) translations, and to turn off fault interrupts. When the SMMU hardware 308 references the termination context bank (e.g., as a result of a re-mapping of a stream as described above), the SMMU hardware 308 may operate in accordance with these context bank configuration settings.

As indicated by the signaling 314, 316 and 318 the device driver 302 may initiate configuration of SMMU-related aspects. For example, the signaling 314 may represent a high-level operating system (HLOS) or related system software (e.g., Unified Extensible Firmware Interface (UEFI)) sending information to the SMMU driver 304 indicating nested streams. The signaling 316 may represent, for example, the SMMU driver 304 writing data associated with such nested streams to registers (not separately shown) in the SMMU hardware 308 or otherwise programming or configuring aspects of the SMMU hardware 308. The signaling 318 may represent the SMMU hardware 308 confirming such programming to the hypervisor 310. The signaling 320 may represent an acknowledgement by virtualization logic 322 in the hypervisor 310. It should be understood that although for purposes of clarity only a single SMMU has been referenced in the examples herein, there may be more than one SMMU. Similarly, although not described herein for purposes of clarity, a hypervisor may communicate with more than one SMMU. In a system having more than one SMMU, each SMMU may be initialized in the manner described herein and may operate in the same manner described herein with regard to the exemplary (single) SMMU.

The remainder of the sequence diagram 300 may relate to handling a stage-2 translation fault. The signaling 324 may represent the SMMU client 306 indicating the occurrence of a stage-2 translation fault associated with a memory transaction. The signaling 326 may represent the SMMU hardware issuing a stage-2 fault interrupt request (IRQ). The signaling 328 may represent termination logic 330 in the hypervisor 310 responding to the interrupt request by writing to a register (not separately shown) in the SMMU hardware 308 that is configured to redirect the faulty stream to the termination context bank. The signaling 332 may represent the SMMU hardware 308 indicating termination of the memory transaction to the SMMU client 306. The signaling 334 may represent a bus error. As described above, the hypervisor 310 may place a unique identifier, such as 0x0, onto a system interconnect bus (not shown in FIG. 3) as a substitute in the absence of a translated address, and the system interconnect bus may report a bus error to the device driver 302. The device driver 302 may decode the bus error to determine which stream is associated with the bus error and then take remedial action as described above.

The use of the termination context bank by the SMMU hardware 308 may, in effect, provide a sink or “jail” from which potentially disruptive results of translation faults may be prevented from emanating. If instead of re-mapping a stream to the termination context bank in response to a translation fault, the stream were to remain mapped to the translation context bank in which that translation fault arose, any further translations associated with that stream following an initial translation fault may be handled in the same manner as the initial translation fault, potentially including placing potentially disruptive faulty addresses on the system interconnect bus, issuing potentially disruptive fault interrupts, etc. Instead, with a translation mode of the termination context bank set to terminate translations, the SMMU hardware 308 may be prevented from placing faulty addresses on the system interconnect bus should one or more further stage-2 translation faults occur in association with a stream that has been re-mapped to the termination context bank. And with fault interrupts turned off in the termination context bank, the SMMU hardware 308 may be prevented from issuing fault interrupt requests should one or more further stage-2 translation faults occur in association with a stream that has been re-mapped to the termination context bank. Also, after re-mapping a stream to the termination context bank the hypervisor 310 may have cleared a fault status indication in a register (not separately shown) of the SMMU hardware 308, thereby masking the occurrence of the translation fault from the device driver 302. Instead of the device driver 302 responding in a generic and potentially disruptive manner to such a fault status indication, the device driver 302 may be alerted of an error condition by a system interconnect bus error as described above, which the device driver 302 may be able to decode and then handle in a more focused manner (e.g., by determining which of multiple possible use cases is implicated, and taking a remedial action based on that use case, as described above).

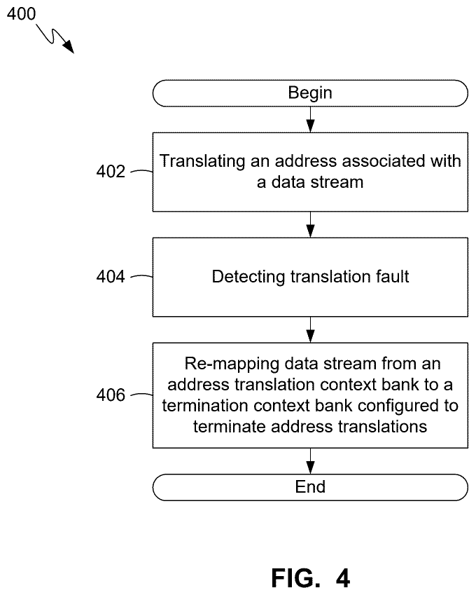

In FIG. 4, a method 400 for handling SMMU translation faults is illustrated in flowchart form. As indicated by block 402, there may be a translation of an address associated with a data stream. Such an address translation may be a stage-2 translation by an SMMU. As indicated by block 404, a translation fault associated with the translation may be detected. This detection may be performed or controlled by a hypervisor. As indicated by block 406, in response to detecting the translation fault the data stream may be re-mapped from an address translation context bank to a termination context bank configured to terminate address translations. The re-mapping may be performed or controlled by the hypervisor.

Execution of software or firmware elements stored or residing in the system memory 104 (FIG. 1) or other memory or non-transitory storage medium may perform or control aspects of any of the above-described methods or configure aspects any of the above-described systems or circuitry. Any such memory or other non-transitory storage medium having software/firmware stored therein in computer-readable form for execution by processor hardware may be an example of a “computer-readable medium,” as the term is understood in the patent lexicon.

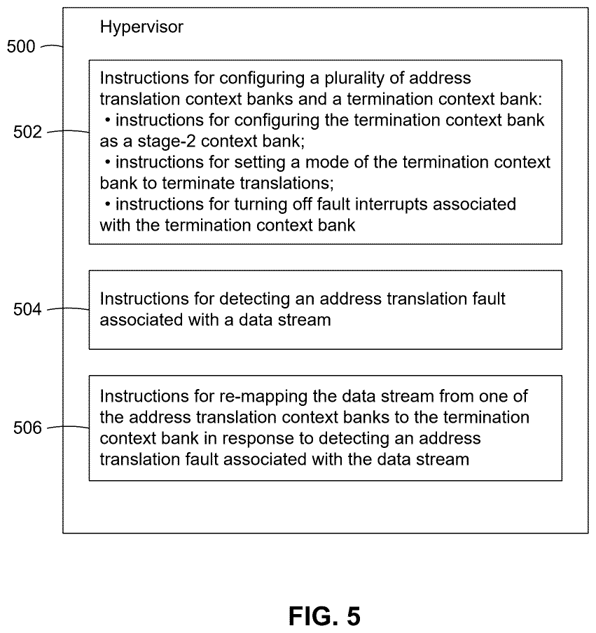

In FIG. 5, aspects of a hypervisor 500 are shown in conceptual form. The hypervisor 500 may be an example of any of the above-described hypervisors 120 (FIG. 1) 204 (FIG. 2) or 310 (FIG. 3). The hypervisor 500 may include context bank configuring code or instructions 502. Such instructions 502 may include instructions for configuring a plurality of address translation context banks and a termination context bank. The instructions 502 may include instructions for configuring the termination context bank as a stage-2 context bank, instructions for setting the mode of the termination context bank to terminate (i.e., abort) translations, and instructions for turning off fault interrupts associated with the termination context bank. The hypervisor 500 may further include instructions 504 for detecting stage-2 translation faults associated with a data stream. The hypervisor 500 may still further include instructions 506 for re-mapping the data stream from an address translation context bank to the termination context bank in response to detecting a translation fault associated with the data stream.

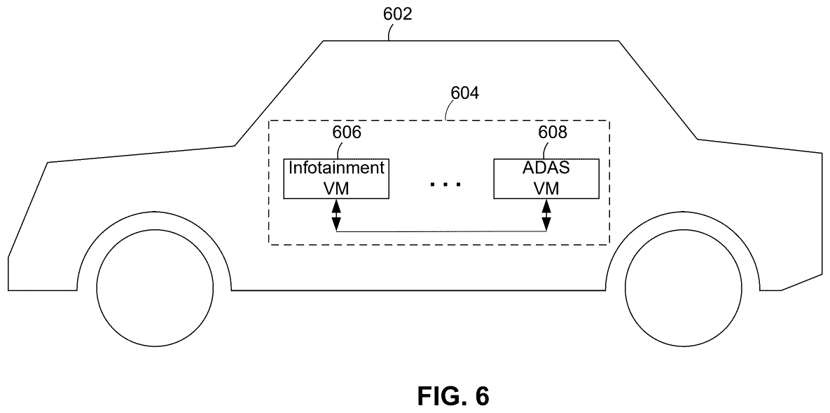

FIG. 6 illustrates an example of an automotive vehicle 602, in which exemplary embodiments of systems, methods, computer-readable media, and other examples of the above-described address translation fault handling may be provided. The vehicle's computing system may be implemented as any number of virtual machines 604. For example, an infotainment virtual machine 606 may be included that supports providing information and entertainment (e.g., audio, maps, etc.) to vehicle occupants. In addition, for example, an Adaptive Driver Assistance Systems (ADAS) virtual machine 608 may be included that supports aspects of vehicle operation.

Operation of the ADAS virtual machine 508, including handling memory transaction faults, may potentially impact vehicle safety, whereas operation of the infotainment virtual machine 606 may not. Accordingly, the solutions described herein may benefit vehicle safety when applied to such safety-related virtual machines. Although a vehicle computing system is used as an example of a safety-related, virtual machine-based computing system, the solutions described herein may also be used in other types of safety-related computing systems or in non-safety-related computing systems.

Implementation examples are described in the following numbered clauses.

1. A method for handling system memory management unit (SMMU) translation faults, comprising:
translating, by the SMMU, an address associated with a data stream;
detecting, by a hypervisor, a translation fault associated with translating the address; and
re-mapping, by the hypervisor, the data stream from an address translation context bank to a termination context bank in response to detecting the translation fault, the termination context bank configured to terminate address translations.

2. The method of claim 1, further comprising clearing, by the hypervisor, a fault status register indication of the translation fault.

3. The method of clause 1 or 2, further comprising:
placing, by the hypervisor, a unique identifier address on a system interconnect bus in response to the translation fault and, after re-mapping the data stream, in response to further translation faults associated with the data stream; and
indicating, by the system interconnect bus, a bus error in response to the unique identifier address.

4. The method of clause 3, further comprising:
detecting, by a client device associated with the data stream, the bus error; and
identifying, by the client device, the data stream in response to detecting the bus error.

5. The method of clause 4, further comprising handling the bus error, by the client device, wherein handling includes restarting a process associated with the data stream or shutting down the process associated with the data stream.

6. The method of any of clauses 1-5, wherein the data stream is associated with a safety virtual machine of a plurality of virtual machines of a computing platform.

7. The method of any of clauses 1-6, wherein the computing platform comprises an automotive computing system.

8. A system for handling address translation faults in a computing device, comprising:
a system memory management unit (SMMU) configured to translating an address associated with a data stream; and
a hypervisor configured to detecting a translation fault associated with the SMMU translating the address, the hypervisor further configured to re-map the data stream from an address translation context bank to a termination context bank in response to detecting the translation fault, the termination context bank configured to terminate address translations.

9. The system of clause 8, wherein the hypervisor is further configured to clear a fault status register indication of the translation fault.

10. The system of clause 8 or 9, wherein the hypervisor is configured to place a unique identifier address on a system interconnect bus in response to the translation fault and, after re-mapping the data stream, in response to further translation faults associated with the data stream, wherein the system interconnect bus is configured to indicate a bus error in response to the unique identifier address.

11. The system of clause 10, further comprising a client device associated with the data stream, wherein:
the client device is configured to detect the bus error; and
the client device is configured to identify the data stream in response to detecting the bus error.

12. The system of clause 11, wherein the client device is further configured to restart a process associated with the data stream or shut down the process associated with the data stream after identifying the data stream.

13. The system of any of clauses 8-12, wherein the data stream is associated with a safety virtual machine of a plurality of virtual machines of a computing platform.

14. The system of any of clauses 8-13, wherein the computing platform comprises an automotive computing system.

15. A computer-readable medium storing computer executable code, comprising:
instructions for configuring a plurality of address translation context banks and a termination context bank;
instructions for detecting an address translation fault associated with a data stream; and
instructions for re-mapping the data stream from one of the address translation context banks to the termination context bank in response to detecting an address translation fault associated with the data stream.

16. The computer-readable medium of clause 15, wherein the instructions for configuring the termination context bank include instructions for setting a mode of the termination context bank to terminate translations.

17. The computer-readable medium of clause 15 or 16, wherein the instructions for configuring the termination context bank include instructions for turning off fault interrupts associated with the termination context bank.

18. The computer-readable medium of any of clauses 15-17, further comprising instructions for placing a unique identifier address on a system interconnect bus in response to the address translation fault and, after re-mapping the data stream, in response to further translation faults associated with the data stream.

19. The computer-readable medium of any of clauses 15-18, wherein the hypervisor is operable on a computing platform having at least one safety virtual machine and at least one non-safety virtual machine.

20. The computer-readable medium of any of clauses 15-19, wherein the computing platform comprises an automotive computing system.

Alternative embodiments will become apparent to one of ordinary skill in the art to which the invention pertains. Therefore, although selected aspects have been illustrated and described in detail, it will be understood that various substitutions and alterations may be made therein.

What is claimed is:

1. A method for handling system memory management unit (SMMU) translation faults, comprising:
translating, by the SMMU, an address associated with a data stream;
detecting, by a hypervisor, a translation fault associated with translating the address; and
re-mapping, by the hypervisor, the data stream from an address translation context bank to a termination context bank in response to detecting the translation fault, the termination context bank configured to terminate address translations.

2. The method of claim 1, further comprising clearing, by the hypervisor, a fault status register indication of the translation fault.

3. The method of claim 1, further comprising:
placing, by the hypervisor, a unique identifier address on a system interconnect bus in response to the translation fault and, after re-mapping the data stream, in response to further translation faults associated with the data stream; and
indicating, by the system interconnect bus, a bus error in response to the unique identifier address.

4. The method of claim 3, further comprising:
detecting, by a client device associated with the data stream, the bus error; and
identifying, by the client device, the data stream in response to detecting the bus error.

5. The method of claim 4, further comprising handling the bus error, by the client device, wherein handling includes restarting a process associated with the data stream or shutting down the process associated with the data stream.

6. The method of claim 1, wherein the data stream is associated with a safety virtual machine of a plurality of virtual machines of a computing platform.

7. The method of claim 6, wherein the computing platform comprises an automotive computing system.

8. A system for handling address translation faults in a computing device, comprising:
a system memory management unit (SMMU) configured to translating an address associated with a data stream; and
a hypervisor configured to detecting a translation fault associated with the SMMU translating the address, the hypervisor further configured to re-map the data stream from an address translation context bank to a termination context bank in response to detecting the translation fault, the termination context bank configured to terminate address translations.

9. The system of claim 8, wherein the hypervisor is further configured to clear a fault status register indication of the translation fault.

10. The system of claim 8, wherein the hypervisor is configured to place a unique identifier address on a system interconnect bus in response to the translation fault and, after re-mapping the data stream, in response to further translation faults associated with the data stream, wherein the system interconnect bus is configured to indicate a bus error in response to the unique identifier address.

11. The system of claim 10, further comprising a client device associated with the data stream, wherein:
the client device is configured to detect the bus error; and
the client device is configured to identify the data stream in response to detecting the bus error.

12. The system of claim 11, wherein the client device is further configured to restart a process associated with the data stream or shut down the process associated with the data stream after identifying the data stream.

13. The system of claim 8, wherein the data stream is associated with a safety virtual machine of a plurality of virtual machines of a computing platform.

14. The system of claim 13, wherein the computing platform comprises an automotive computing system.

15. A computer-readable medium storing computer executable code, comprising:
instructions for configuring a plurality of address translation context banks and a termination context bank;
instructions for detecting an address translation fault associated with a data stream; and
instructions for re-mapping the data stream from one of the address translation context banks to the termination context bank in response to detecting an address translation fault associated with the data stream.

16. The computer-readable medium of claim 15, wherein the instructions for configuring the termination context bank include instructions for setting a mode of the termination context bank to terminate translations.

17. The computer-readable medium of claim 15, wherein the instructions for configuring the termination context bank include instructions for turning off fault interrupts associated with the termination context bank.

18. The computer-readable medium of claim 15, further comprising instructions for placing a unique identifier address on a system interconnect bus in response to the address translation fault and, after re-mapping the data stream, in response to further translation faults associated with the data stream.

19. The computer-readable medium of claim 15, wherein the hypervisor is operable on a computing platform having at least one safety virtual machine and at least one non-safety virtual machine.

20. The computer-readable medium of claim 19, wherein the computing platform comprises an automotive computing system.
